(19) United States
(12) Patent Application Publication
(10) Pub. No.: US 2010/0200055 A1
(43) Pub. Date: Aug. 12, 2010

(54) METHOD OF MANUFACTURING A DYE SENSITIZED SOLAR CELL BY ATMOSPHERIC PRESSURE ATOMIC LAYER DEPOSITION (ALD)

(76) Inventors: John R. Fyson, London (GB); Julie Baker, Leavesden (GB); Nicholas J. Dartnell, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/670,861

(22) PCT Filed: Jul. 2, 2008
(86) PCT No.: PCT/GB2008/002291

§ 371 Date: Jan. 27, 2010

(30) Foreign Application Priority Data
Aug. 4, 2007 (GB) 0715178.0

(51) Int. Cl. H01L 31/00; H01L 31/18

(52) U.S. Cl. 136/256; 438/57; 257/E31.001

(57) ABSTRACT

A method of laying down one or more layers of material to reduce electrolytic reaction whilst allowing electron transfer between a conductive substrate and a light collecting charge separating layer, the layer being deposited between the conductive substrate and the light collecting charge separating layer and/or over the light collecting charge separating layer, the layer being deposited by atmospheric pressure atomic layer deposition.

### FIELD OF THE INVENTION

This invention relates to solar cells, in particular to those of the type known as dye sensitized cells and the reduction/prevention of unwanted back reaction.

### BACKGROUND OF THE INVENTION

Conventional dye-sensitized solar cells as described by Gratzel consist of a transparent conducting substrate such as ITO on glass or plastic, on top of which is a sintered layer of titanium dioxide nanoparticles coated with dye (the anode). A hole-carrying electrolyte that typically contains iodide/tri-iodide as the electron (or hole) transfer agent is placed within the pores of and on top of this layer. The solar cell sandwich is completed by putting on top of the electrolyte a catalytic conducting electrode, often made with platinum as the catalyst (the cathode). When light is shone on the cell, the dye is excited and an electron is injected into the titanium dioxide structure. The excited, now positively charged dye oxidises the reduced form of the redox couple in the electrolyte to its oxidised form e.g. iodide goes to tri-iodide. This may now diffuse towards the platinum electrode. When the cell is connected to a load the electrons from the anode pass through the load to the cathode and at the cathode the oxidised form of the redox couple is reduced e.g. tri-iodide to iodide, completing the reaction. The oxidised form of the redox couple may also react with an electron at the anode, where the electrolyte is at an interface with either the ITO or the titanium dioxide surface—this is known as a ‘back reaction’. If this happens, the cell potential and current will be diminished. The anode conducting material can be carefully chosen to reduce this ‘back reaction’ but this is not completely possible resulting in a reduction of cell efficiency.

The use of a recombination blocking layer is known in dye sensitised solar cells primarily as a layer between the titania and the dye but also as a layer located between the active titania mesoporous layer and the substrate electrode. This latter case has been solved by others through creating an underlayer by means of sputtering, spray-pyrolysis, hydrolysis of a precursor, microwave chemical bath deposition, electro deposition or dip coating. These are inconvenient methods in that they involve solution chemistry or vacuum operations and are not necessarily conformal to the existing surface.

US 2005/0098205 discloses growing an underlayer of titania (in a Photovoltaic device) to prevent unwanted contact between a material filling the templated structure and the substrate/base electrode. This layer is grown using atomic layer deposition (ALD) but this is not disclosed as an atmospheric pressure step and so has the disadvantage of high equipment cost, plus the additional time and inconvenience of a vacuum based process.

US 2005/0098204 discloses growing a recombination-reducing inorganic layer such as alumina between the first and second or second and third charge transfer material, but not adjacent to the substrate. This layer is again grown using ALD and, as for the previous example, this is not disclosed as an atmospheric pressure step and so has the disadvantages of high equipment cost plus the additional time and inconvenience of a vacuum based process.

US 2006/0162769 discloses a solution based alternative, to give a conformal coating using chemical processes akin to ALD, i.e. hydrolysis of a metal alkoxide. The process is used to coat, for example, alumina around the mesoporous titania in a dye sensitised solar cell. This process has the inconvenience of solution chemistry, e.g. solvent and solution preparation and increased steps in the process such as a post treatment drying step/period.

### PROBLEM TO BE SOLVED BY THE INVENTION

The invention aims to provide a process in which unwanted “back reaction” of the redox couple is reduced or prevented completely.

By using atmospheric pressure atomic layer deposition, AP-ALD, a convenient method of depositing the recombination blocking layer has been identified, which is conformal to the existing surface and could be applicable to a roll to roll manufacturing process. This layer may be deposited onto the conducting substrate of the anode prior to the laying down of the light collecting charge separating layer and/or may be conformally deposited over the light collecting charge separating layer prior to or after the dyeing step. Examples of the light collecting charge separating layer are mesoporous titania, zinc oxide, tin oxide.

### SUMMARY OF THE INVENTION

The invention is to coat a thin layer of material onto a conducting electrode of a cell (i.e. a recombination blocking layer) by AP-ALD such that electrons can still conduct to the electrode with little resistance but reduces or prevents the unwanted back reaction of the redox couple at an electrode/electrolyte interface. Such a layer might be titanium dioxide deposited from reacting titanium tetrachloride with water on the surface of the electrode from an AP-ALD device. Alternative layers might be an oxide which might include aluminium oxide, niobium pentoxide or zinc oxide.

According to the present invention there is provided a method of laying down one or more layers of material to reduce electrolytic reaction whilst allowing electron transfer between a conductive substrate and a light collecting charge separating layer, the layer being deposited between the conductive substrate and the light collecting charge separating layer and/or over the light collecting charge separating layer, the layer being deposited by simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, optionally repeated a plurality of times, wherein the first reactive gaseous material is capable of reacting with a substrate surface treated with the second reactive gaseous material.

### ADVANTAGEOUS EFFECT OF THE INVENTION

By using AP-ALD as a deposition method, thin recombination blocking layers may be deposited either on the substrate of the anode and/or conformally over the light collecting charge separating layer, prior to or after the dyeing step without the disadvantage of cost, additional time and inconvenience of a vacuum based process or the solvent and solution preparation and increased steps involved with a solution process such as a post treatment dyeing step/period.

### BRIEF DESCRIPTION OF THE DRAWINGS

The invention will now be described with reference to the accompanying drawings in which:

FIG. 1 is a flow chart describing the steps of the process used in the present invention;

FIG. 2 is a cross sectional side view of an embodiment of a distribution manifold for atomic layer deposition that can be used in the present process;

FIG. 3 is a cross sectional side view of an embodiment of the distribution of gaseous materials to a substrate that is subject to thin film deposition;

FIGS. 4A and 4B are cross sectional views of an embodiment of the distribution of gaseous materials schematically showing the accompanying deposition operation;

FIG. 5 is a graph illustrating the effect of a 10 nm AP-ALD deposited TiO₂ recombination blocking layer on performance at 0.1 sun, where the layer is deposited directly on the ITO surface;

FIG. 6 is a graph illustrating the effect of AP-ALD deposited TiO₂ recombination blocking layer thickness on dark current, where these layers are deposited directly on the ITO surface;

FIG. 7 is a graph illustrating the effect of a 3 nm AP-ALD ZnO recombination blocking layer deposited above the nanoporous TiO₂ layer on performance at 0.1 sun;

FIG. 8 is a graph illustrating the effect of combining a 3 nm AP-ALD TiO₂ recombination blocking layer deposited on the ITO surface and a ZnO recombination blocking layer deposited above the nanoporous TiO₂ layer on performance at 0.1 sun; and

FIG. 9 is a graph illustrating the effect of AP-ALD recombination blocking layers on dark current.

### DETAILED DESCRIPTION OF THE INVENTION

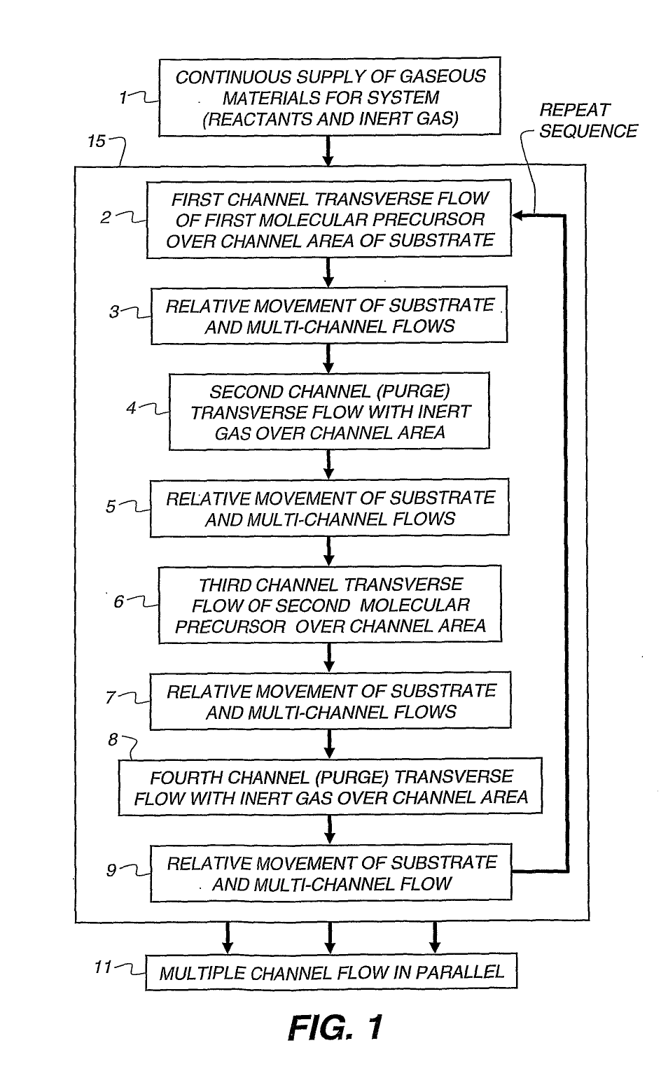

FIG. 1 is a generalized step diagram of a process for practicing the present invention. Two reactive gases are used, a first molecular precursor and a second molecular precursor. Gases are supplied from a gas source and can be delivered to the substrate, for example, via a distribution manifold. Metering and valving apparatus for providing gaseous materials to the distribution manifold can be used.

As shown in Step 1, a continuous supply of gaseous materials for the system is provided for depositing a thin film of material on a substrate. The Steps in Sequence 15 are sequentially applied. In Step 2, with respect to a given area of the substrate (referred to as the channel area), a first molecular precursor or reactive gaseous material is directed to flow in a first channel transversely over the channel area of the substrate and reacts therewith. In Step 3 relative movement of the substrate and the multi-channel flows in the system occurs, which sets the stage for Step 4, in which second channel (purge) flow with inert gas occurs over the given channel area. Then, in Step 5, relative movement of the substrate and the multi-channel flows sets the stage for Step 6, in which the given channel area is subjected to atomic layer deposition in which a second molecular precursor now transversely flows (substantially parallel to the surface of the substrate) over the given channel area of the substrate and reacts with the previous layer on the substrate to produce (theoretically) a monolayer of a desired material. Often in such processes, a first molecular precursor is a metal-containing compound in gas form (for example, a metallic compound such as titanium tetrachloride) and the material deposited is a metal-containing compound (for example titanium dioxide). In such an embodiment, the second molecular precursor can be, for example, a non-metallic oxidizing compound or hydrolyzing compound, e.g. water.

In Step 7, relative movement of the substrate and the multi-channel flows then sets the stage for Step 8 in which again an inert gas is used, this time to sweep excess second molecular precursor from the given channel area from the previous Step 6. In Step 9, relative movement of the substrate and the multi-channels occurs again, which sets the stage for a repeat sequence, back to Step 2. The cycle is repeated as many times as is necessary to establish a desired film or layer. The steps may be repeated with respect to a given channel area of the substrate, corresponding to the area covered by a flow channel. Meanwhile the various channels are being supplied with the necessary gaseous materials in Step 1. Simultaneous with the sequence of box 15 in FIG. 1, other adjacent channel areas are being processed simultaneously, which results in multiple channel flows in parallel, as indicated in overall Step 11.

The primary purpose of the second molecular precursor is to condition the substrate surface back toward reactivity with the first molecular precursor. The second molecular precursor also provides material as a molecular gas to combine with one or more metal compounds at the surface, forming compounds such as an oxide, nitride, sulfide, etc, with the freshly deposited metal-containing precursor.

The continuous ALD purge does not need to use a vacuum purge to remove a molecular precursor after applying it to the substrate.

Assuming that two reactant gases, AX and BY, are used, when the reaction gas AX flow is supplied and flowed over a given substrate area, atoms of the reaction gas AX are chemically adsorbed on a substrate, resulting in a layer of A and a surface of ligand X (associative chemisorptions) (Step 2). Then, the remaining reaction gas AX is purged with an inert gas (Step 4). Then, the flow of reaction gas BY and a chemical reaction between AX (surface) and BY (gas) occurs, resulting in a molecular layer of AB on the substrate (dissociative chemisorptions) (Step 6). The remaining gas BY and by-products of the reaction are purged (Step 8). The thickness of the thin film can be increased by repeating the process cycle (steps 2-9).

Because the film can be deposited one monolayer at a time it tends to be conformal and have uniform thickness.

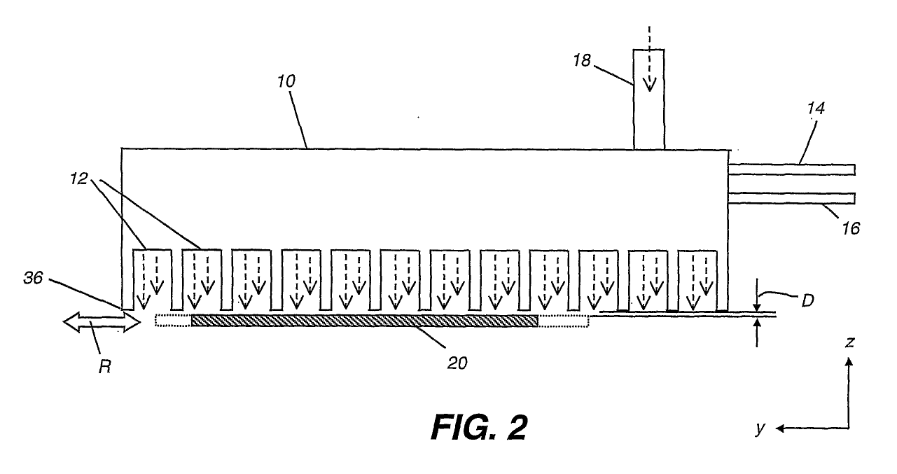

Referring now to FIG. 2, there is shown a cross-sectional side view of one embodiment of a distribution manifold 10 that can be used in the present process for atomic layer deposition onto a substrate 20. Distribution manifold 10 has a gas inlet port 14 for accepting a first gaseous material, a gas inlet port 16 for accepting a second gaseous material, and a gas inlet port 18 for accepting a third gaseous material. These gases are emitted at an output face 36 via output channels 12, having a structural arrangement described subsequently. The arrows in FIG. 2 refer to the diffusive transport of the gaseous material, and not the flow, received from an output channel. The flow is substantially directed out of the page of the figure.

Gas inlet ports 14 and 16 are adapted to accept first and second gases that react sequentially on the substrate surface to effect ALD deposition, and gas inlet port 18 receives a purge gas that is inert with respect to the first and second gases. Distribution manifold 10 is spaced a distance D from substrate 20, provided on a substrate support. Reciprocating motion can be provided between substrate 20 and distribution manifold 10, either by movement of substrate 20, by movement of distribution manifold 10, or by movement of both substrate 20 and distribution manifold 10. In the particular embodiment shown in FIG. 2, substrate 20 is moved across output face 36 in reciprocating fashion, as indicated by the arrow R and by phantom outlines to the right and left of substrate 20 in FIG. 2. It should be noted that reciprocating motion is not always required for thin-film deposition using distribution manifold 10. Other types of relative motion between substrate 20 and distribution manifold 10 could also be provided, such as movement of either substrate 20 or distribution manifold 10 in one or more directions.

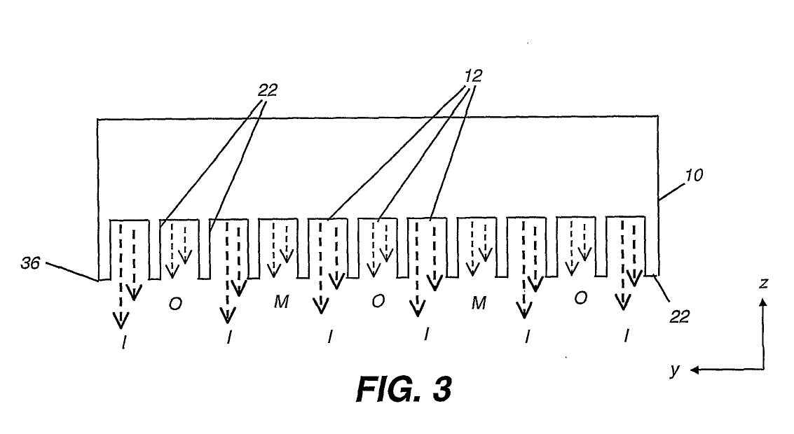

The cross-sectional view of FIG. 3 shows gas flows emitted over a portion of front face 36 of distribution manifold 10. In this particular arrangement, each output channel 12 is in gaseous flow communication with one of gas inlet ports 14, 16 or 18 seen in FIG. 2. Each output channel 12 delivers typically a first reactant gaseous material O, or a second reactant gaseous material M, or a third inert gaseous material I.

FIG. 3 shows a relatively basic or simple arrangement of gases. It is possible that a plurality of non-metal deposition precursors (like material O) or a plurality of metal-containing precursor materials (like material M) may be delivered sequentially at various ports in a thin-film single deposition. Alternately, a mixture of reactant gases, for example, a mixture of metal precursor materials or a mixture of metal and non-metal precursors may be applied at a single output channel when making complex thin film materials, for example, having alternate layers of metals or having lesser amounts of dopants admixed in a metal oxide material. The critical requirement is that an inert stream labeled I should separate any reactant channels in which the gases are likely to react with each other. First and second reactant gaseous materials O and M react with each other to effect ALD deposition, but neither reactant gaseous material O nor M reacts with inert gaseous material I.

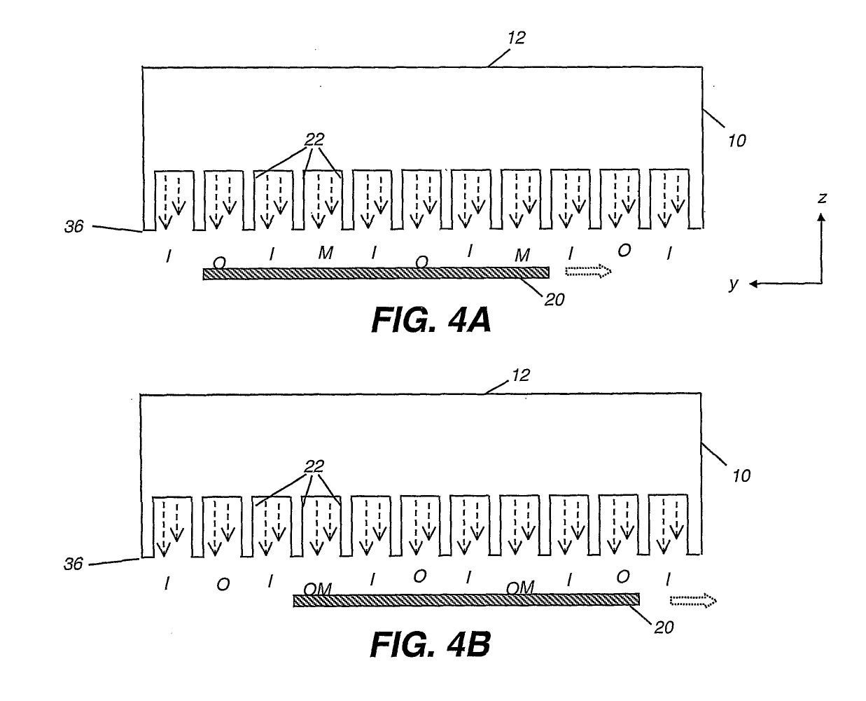

The cross-sectional views of FIGS. 4A and 4B show, in simplified schematic form, the ALD coating operation performed as substrate 20 passes along output face 36 of distribution manifold 10 when delivering reactant gaseous materials O and M. In FIG. 4A, the surface of substrate 20 first receives an oxidizing material from output channels 12 designated as delivering first reactant gaseous material O. The surface of the substrate now contains a partially reacted form of material O, which is susceptible to reaction with material M. Then, as substrate 20 passes into the path of the metal compound of second reactant gaseous material M, the reaction with M takes place, forming a metallic oxide or some other thin film material that can be formed from two reactant gaseous materials.

As FIGS. 4A and 4B show, inert gaseous material I is provided in every alternate output channel 12, between the flows of first and second reactant gaseous materials O and M. Sequential output channels 12 are adjacent, that is, share a common boundary, formed by partitions 22 in the embodiments shown. Here, output channels 12 are defined and separated from each other by partitions 22 that extend perpendicular to the surface of substrate 20.

Notably, there are no vacuum channels interspersed between the output channels 12, that is, no vacuum channels on either side of a channel delivering gaseous materials to draw the gaseous materials around the partitions. This advantageous, compact arrangement is possible because of the innovative gas flow that is used. Unlike gas delivery arrays of earlier processes that apply substantially vertical (that is, perpendicular) gas flows against the substrate and should then draw off spent gases in the opposite vertical direction, distribution manifold 10 directs a gas flow (preferably substantially laminar in one embodiment) along the surface for each reactant and inert gas and handles spent gases and reaction by-products in a different manner. The gas flow used in the present invention is directed along and generally parallel to the plane of the substrate surface. In other words, the flow of gases is substantially transverse to the plane of a substrate rather than perpendicular to the substrate being treated.

The above described method and apparatus are used in the present invention to lay down a blocking layer.

### Example 1

### Improved V_{Oc} (Open Circuit Voltage) and I_{Sc} (Short Circuit Current) Through Use of a TiO₂ Recombination Blocking Layer Deposited on the ITO Surface

A sample of 50 Ω/square ITO-PET was taken and a 10 nm TiO₂ recombination blocking layer was deposited onto the ITO layer using AP-ALD. The conditions used for the deposition are shown in Table 1.

TABLE 1
AP-ALD conditions used to deposit 10 nm TiO₂ recombination blocking
layer

| Bubbler 1 | Material | Water | |
|---|---|---|---|
| | Flow rate | 22 | ml/min |
| Bubbler 2 | Material | TiCl₄ | |
| | Flow rate | 48 | ml/min |
| Carrier gas flow | Inert (N₂) | 2000 | ml/min |
| | Water (compressed air) | 300 | ml/min |
| | Metal (N₂) | 200 | ml/min |
| Temperature | Platen | 95-105° | C. |
| | Coating Head | 50° | C. |
| Deposition Settings | No. of oscillations | 50 | |
| | Platen speed | 25 | mm/sec |
| | Head height | 55 | μm |

| | | |
|---|---|---|
| Thickness of TiO₂ Layer | ~10 | nm |

This support was then used to make a dye sensitised solar cell (cell A). To act as a control, an untreated piece of 50 Ω/square ITO-PET was used to create another dye sensitised solar cell (control).

Some titanium dioxide was dried in an oven at 90° C. overnight prior to use. This was a titanium dioxide sample which had an average particle size of 21 nm (Degussa Aeroxide P25, specific surface area (BET)=50+/−15 m²/g). The flexible dye sensitised solar cells relating to the invention (cell A) and the comparison (control) were fabricated as follows.

Approximately 15-20 μm thick nanoporous TiO₂ films were deposited onto both the sample of 50 Ω/square ITO-PET covered with the 10 nm AP-ALD TiO₂ layer and the untreated sample of 50 Ω/square ITO-PET by dispersing the dried TiO₂ in a mixture of dry Methyl Ethyl Ketone and Ethyl Acetate in the following amounts for each sample:

| | |
|---|---|
| Degussa P25 TiO₂ (21 nm particles) | 1.35 g |
| Methyl Ethyl Ketone | 45 g |
| Ethyl Acetate | 5 g |

The resulting mixtures were sonicated for 15 minutes before being sprayed onto the two samples of conducting plastic substrate from a distance of approx 25 cm using a SATAminijet 3 HVLP spray gun with a 1 mm nozzle and 2 bar nitrogen carrier gas. The layers were allowed to dry in an oven at 90° C. for one hour, before being placed between two sheets of Teflon, sandwiched between two polished stainless steel bolsters and compressed with a pressure of 3.75 tonnes/cm² for 15 seconds. The sintered layers were then allowed to dry for a further hour at 90° C.

The sintered layers were then sensitised by placing them in a 3×10⁺⁴ mol dm⁻³ ethanolic solution of ruthenium cis-bis-isothiocyanato bis(2,2′bipyridyl-4,4′dicarboxylic acid) overnight.

Platinum coated stainless steel foil electrodes were prepared by sputter deposition under vacuum.

The dye sensitised TiO₂ layers and the platinum counter electrode were arranged in a sandwich type configuration with an ionic liquid electrolyte contained within a gasket. The electrolyte comprised:

### 0.1M LiI

0.6M DMPII (1,2,dimethyl-3-propyl-imidazolium iodide)

### 0.05M I₂

### 0.5M N-methylbenzimidazole

### Solvent=MPN (Methoxypropionitrile)

Following fabrication, the dye sensitised solar cells were characterised by placing them under a source that artificially replicated the solar spectrum in the visible region to provide an illumination of 0.10 sun.

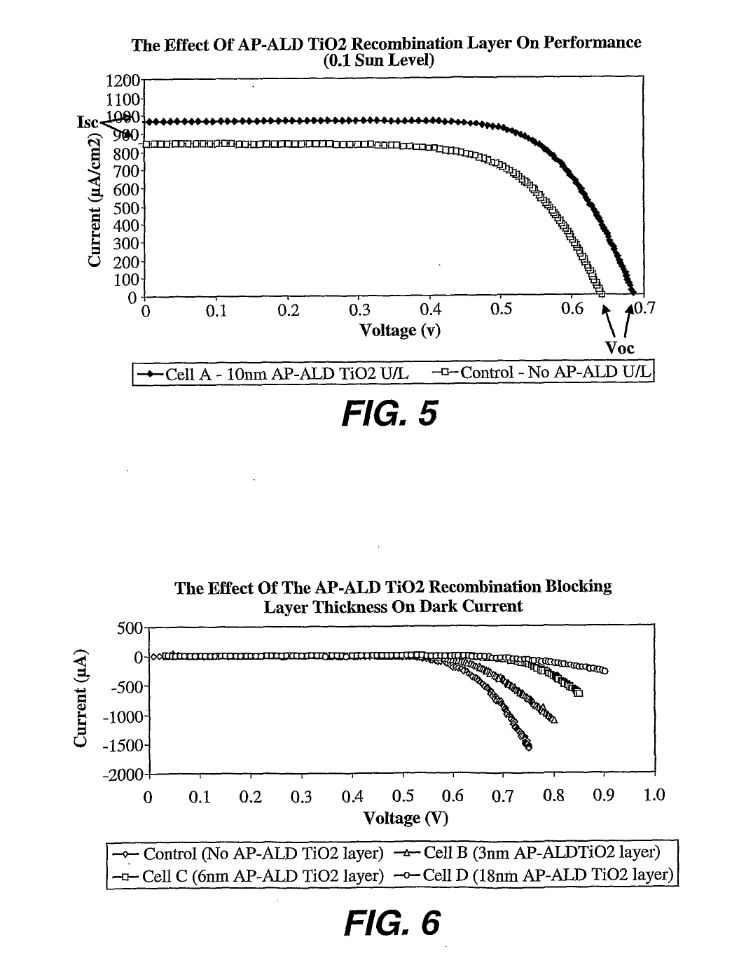

The data in FIG. 5 demonstrate that cell A (the invention comprising a 10 nm AP-ALD TiO₂ recombination blocking layer) has higher open circuit voltage (Voc) and short circuit current (Isc) compared to the control where no recombination blocking layer was employed.

### Example 2

### Effect of Thickness of AP-ALD TiO₂ Recombination Blocking Layer, Deposited on the ITO Surface, on Dark Current

One way of assessing the effectiveness of a recombination blocking layer is to measure the dark current.

Samples of 13 Ω/square ITO-PEN were taken and various thicknesses of TiO₂ recombination blocking layers were deposited onto the ITO layer of each using AP-ALD. The conditions used for the depositions are shown in Table 2.

TABLE 2
AP-ALD conditions used to deposit various thicknesses of TiO₂
recombination blocking layer for cells B, C & D

| Bubbler 1 | Material | Water | |
|---|---|---|---|
| | Flow rate | 22 | ml/min |
| Bubbler 2 | Material | TiCl₄ | |
| | Flow rate | 48 | ml/min |
| Carrier gas flow | Inert (N₂) | 2000 | ml/min |
| | Water (compressed air) | 300 | ml/min |
| | Metal (N₂) | 200 | ml/min |
| Temperature | Platen | 95-105° | C. |
| | Coating Head | 50° | C. |
| Deposition Settings | Platen speed | 25 | mm/sec |
| | Head height | 55 | μm |
| Cell B | No. of oscillations | 10 | |
| | Thickness of TiO₂ Layer | ~3 | nm |
| Cell C | No. of oscillations | 25 | |
| | Thickness of TiO₂ Layer | ~6 | nm |
| Cell D | No. of oscillations | 50 | |
| | Thickness of TiO₂ Layer | ~18 | nm |

Dye sensitised solar cells were then fabricated using the same method described in example 1. The same control from example 1 (i.e. no recombination blocking layer present but with 13 Ω/square ITO-PEN as the anode substrate) was used in this example.

The dark currents for cells B (2 nm AP-ALD TiO₂ recombination blocking layer), C (6 nm AP-ALD TiO₂ recombination blocking layer), D (14 nm AP-ALD TiO₂ recombination blocking layer) and the control cell (no AP-ALD TiO₂ recombination blocking layer) were then measured and are shown in FIG. 6.

FIG. 6 demonstrates that as the thickness of the AP-ALD TiO₂ recombination blocking layer is increased from zero to 18 nm, so a higher voltage is required before current will flow in the opposite direction due to recombination back reactions.

### Example 3

### Improved V_{Oc} (Open Circuit Voltage) Through Use of a ZnO Recombination Blocking Layer Conformally Deposited on the Surface of the Nanoporous TiO₂ Layer

Some titanium dioxide was dried in an oven at 90° C. overnight prior to use. This was a titanium dioxide sample which had an average particle size of 21 nm (Degussa Aeroxide P25, specific surface area (BET)=50+/−15 m²/g). The flexible dye sensitised solar cells relating to the invention (cell E) and the comparison (control) were fabricated as follows.

Approximately 30 μm thick nanoporous TiO₂ films were deposited onto two separate pieces of 13 Ω/square ITO-PEN by dispersing the dried TiO₂ in a mixture of dry Methyl Ethyl Ketone and Ethyl Acetate in the following amounts for each sample:

| | |
|---|---|
| Degussa P25 TiO₂ (21 nm particles) | 1.35 g |
| Methyl Ethyl Ketone | 45 g |
| Ethyl Acetate | 5 g |

The resulting mixtures were sonicated for 15 minutes before being sprayed onto the two samples of conducting plastic substrate from a distance of approximately 25 cm using a SATAminijet 3 HVLP spray gun with a 1 mm nozzle and 2 bar nitrogen carrier gas. The layers were allowed to dry in an oven at 90° C. for one hour, before being placed between two sheets of Teflon, sandwiched between two polished stainless steel bolsters and compressed with a pressure of 3.75 tonnes/cm² for 15 seconds. The sintered layers were then allowed to dry for a further hour at 90° C.

For the cell relating to this invention a 3 nm ZnO recombination blocking layer was then conformally deposited onto the surface of the nanoporous TiO₂ layer using AP-ALD. The conditions used for the deposition are shown in Table 3.

TABLE 3
AP-ALD conditions used to deposit 3 nm ZnO recombination
blocking layer

| Bubbler 1 | Material | Water | |
|---|---|---|---|
| | Flow rate | 22 | ml/min |
| Bubbler 2 | Material | Diethyl Zinc | |
| | Flow rate | 49 | ml/min |
| Carrier gas flow | Inert (N₂) | 2000 | ml/min |
| | Water (compressed air) | 300 | ml/min |
| | Metal (N₂) | 200 | ml/min |
| Temperature | Platen | 95-105° | C. |
| | Coating Head | 50° | C. |
| Deposition Settings | No. of oscillations | 40 | |
| | Platen speed | 50 | mm/sec |
| | Head height | 55 | μm |

| | | |
|---|---|---|
| Thickness of ZnO Layer | ~3 | nm |

The cell relating to the comparison (control) did not have a ZnO layer deposited on the surface of the nanoporous TiO₂ layer.

The samples were then sensitised by placing them in a 3×10⁺⁴ mol dm⁻³ ethanolic solution of ruthenium cis-bis-isothiocyanato bis(2,2′bipyridyl-4,4′dicarboxylic acid) overnight.

Platinum coated stainless steel foil electrodes were prepared by sputter deposition under vacuum.

The dye sensitised TiO₂ layers and the platinum counter electrode were arranged in a sandwich type configuration with an ionic liquid electrolyte in between. The electrolyte comprised:

### 0.1M LiI

0.6M DMPII (1,2,dimethyl-3-propyl-imidazolium iodide)

### 0.05M I₂

### 0.5M N-methylbenzimidazole

### Solvent=MPN (Methoxypropionitrile)

Following fabrication, the dye sensitised solar cells were characterised by placing under a source that artificially replicated the solar spectrum in the visible region to provide an illumination of 0.10 sun.

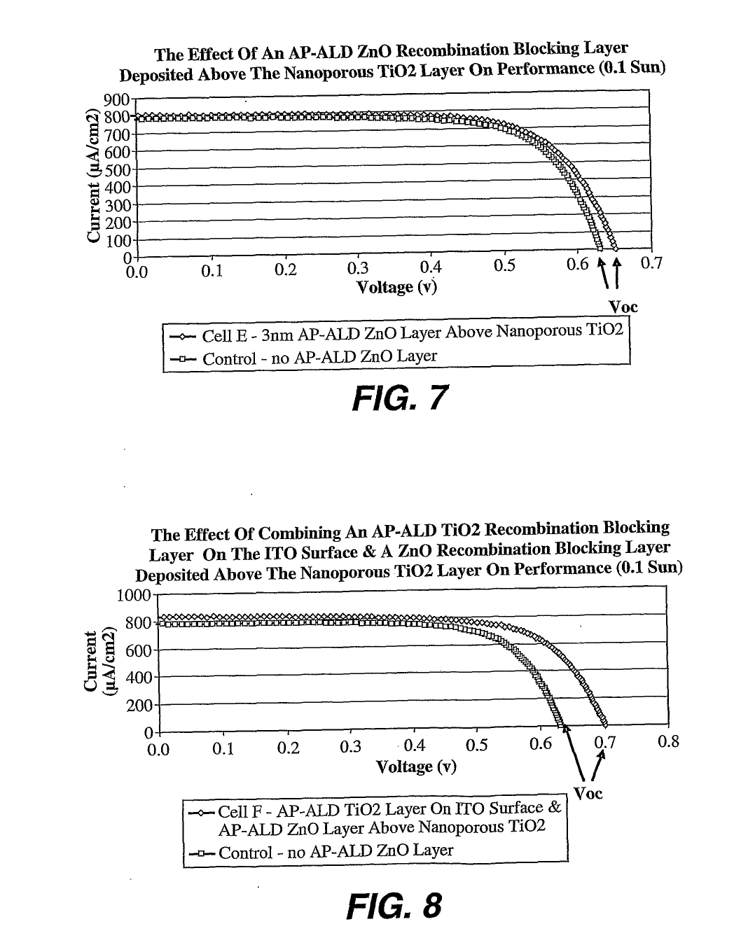

The data in FIG. 7 demonstrate that cell E (the invention comprising a 3 nm AP-ALD ZnO recombination blocking layer deposited on the surface of the nanoporous TiO₂ layer) has higher open circuit voltage (Voc) compared to the control where no recombination blocking layer was employed.

### Example 4

### Improved V_{oc} (Open Circuit Voltage) Through Use of a TiO₂ Recombination Blocking Layer Deposited on the ITO Substrate in Combination with a ZnO Recombination Blocking Layer Conformally Deposited on the Surface of the Nanoporous TiO₂ Layer

A sample of 13 Ω/square ITO-PEN was taken and a 3 nm TiO₂ recombination blocking layer was deposited onto the ITO layer using AP-ALD. The conditions used for the deposition are shown in Table 4.

TABLE 4
AP-ALD conditions used to deposit 3 nm TiO₂ recombination
blocking layer

| Bubbler 1 | Material | Water | |
|---|---|---|---|
| | Flow rate | 22 | ml/min |
| Bubbler 2 | Material | TiCl₄ | |
| | Flow rate | 48 | ml/min |
| Carrier gas flow | Inert (N₂) | 2000 | ml/min |
| | Water (compressed air) | 300 | ml/min |
| | Metal (N₂) | 200 | ml/min |
| Temperature | Platen | 95-105° | C. |
| | Coating Head | 50° | C. |
| Deposition Settings | No. of oscillations | 10 | |
| | Platen speed | 25 | mm/sec |
| | Head height | 55 | μm |

| | | |
|---|---|---|
| Thickness of TiO₂ Layer | ~3 | nm |

This support was then used to make a dye sensitised solar cell (cell F). To act as a control, an untreated piece of 13 Ω/square ITO-PEN was used to create another dye sensitised solar cell (control).

Some titanium dioxide was dried in an oven at 90° C. overnight prior to use. This was a titanium dioxide sample which had an average particle size of 21 nm (Degussa Aeroxide P25, specific surface area (BET)=50+/−15 m²/g). The flexible dye sensitised solar cells relating to the invention (cell F) and the comparison (control) were fabricated as follows.

Approximately 30 μm thick nanoporous TiO₂ films were deposited onto the two separate pieces of 13 Ω/square ITO-PEN by dispersing the dried TiO₂ in a mixture of dry Methyl Ethyl Ketone and Ethyl Acetate in the following amounts for each sample:

| | |
|---|---|
| Degussa P25 TiO₂ (21 nm particles) | 1.35 g |
| Methyl Ethyl Ketone | 45 g |
| Ethyl Acetate | 5 g |

The resulting mixtures were sonicated for 15 minutes before being sprayed onto the two samples of conducting plastic substrate from a distance of approximately 25 cm using a SATAminijet 3 HVLP spray gun with a 1 mm nozzle and 2 bar nitrogen carrier gas. The layers were allowed to dry in an oven at 90° C. for one hour, before being placed between two sheets of Teflon, sandwiched between two polished stainless steel bolsters and compressed with a pressure of 3.75 tonnes/cm² for 15 seconds. The sintered layers were then allowed to dry for a further hour at 90° C.

For the cell relating to this invention (cell F) a 3 nm ZnO recombination blocking layer was then conformally deposited onto the surface of the nanoporous TiO₂ layer using AP-ALD. The conditions used for the deposition are shown in Table 5.

TABLE 5
AP-ALD conditions used to deposit 3 nm ZnO recombination
blocking layer

| Bubbler 1 | Material | Water | |
|---|---|---|---|
| | Flow rate | 22 | ml/min |
| Bubbler 2 | Material | Diethyl Zinc | |
| | Flow rate | 49 | ml/min |
| Carrier gas flow | Inert (N₂) | 2000 | ml/min |
| | Water (compressed air) | 300 | ml/min |
| | Metal (N₂) | 200 | ml/min |
| Temperature | Platen | 95-105° | C. |
| | Coating Head | 50° | C. |
| Deposition Settings | No. of oscillations | 40 | |
| | Platen speed | 50 | mm/sec |
| | Head height | 55 | μm |

| | | |
|---|---|---|
| Thickness of ZnO Layer | ~3 | nm |

The samples were then sensitised by placing them in a 3×10⁻⁴ mol dm⁻³ ethanolic solution of ruthenium cis-bis-isothiocyanato bis(2,2′bipyridyl-4,4′dicarboxylic acid) overnight.

Platinum coated stainless steel foil electrodes were prepared by sputter deposition under vacuum.

The dye sensitised TiO₂ layers and the platinum counter electrode were arranged in a sandwich type configuration with an ionic liquid electrolyte in between. The electrolyte comprised:

### 0.1M LiI

0.6M DMPII (1,2,dimethyl-3-propyl-imidazolium iodide)

### 0.05M I₂

### 0.5M N-methylbenzimidazole

### Solvent=MPN (Methoxypropionitrile)

Following fabrication, the dye sensitised solar cells were characterised by placing under a source that artificially replicated the solar spectrum in the visible region to provide an illumination of 0.10 sun.

The data in FIG. 8 demonstrate that cell F (the invention comprising a 3 nm AP-ALD TiO₂ recombination blocking layer deposited on the ITO surface and a 3 nm AP-ALD ZnO recombination blocking layer deposited on the surface of the nanoporous TiO₂ layer) has considerably higher open circuit voltage (Voc) compared to the control where no recombination blocking layers were employed.

### Example 5

### Effect of the AP-APLD Recombination Blocking Layer on Dark Current

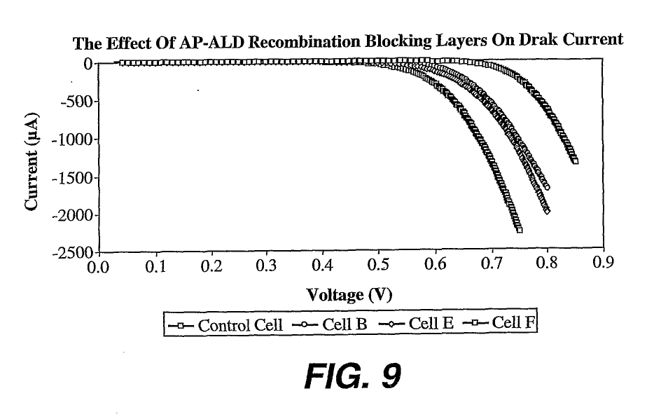

To assess the effectiveness of the various recombination blocking layers, dark currents were measured on cell B (TiO₂ blocking layer on ITO surface), cell E (ZnO blocking layer deposited on the nanoporous TiO2 surface), cell F (TiO₂ blocking layer on ITO surface & ZnO blocking layer deposited on the nanoporous TiO2 surface) and the control (see FIG. 9).

FIG. 9 demonstrates that when either the AP-ALD TiO₂ or ZnO recombination blocking layers were present on the ITO surface or the surface of the nanoporous TiO₂ layer respectively, a higher voltage was required before current will flow in the opposite direction due to recombination back reactions when the cell is not illuminated. When both recombination blocking layers were combined within one cell, even higher voltage was required. This demonstrates a considerable reduction in recombination reactions is present.

These examples demonstrate that AP-ALD can be used to deposit recombination blocking layers which are conformal to the existing surface and could be applicable to a roll to roll manufacturing process employing substrates only compatible with low temperature processing. This layer may be deposited onto the anode substrate prior to the mesoporous titania layer being laid down or may be conformally deposited over the mesoporous titania layer, prior to or after the dyeing step.

The above examples were performed using titanium dioxide. However any metal compound with group VI elements may be used.

The thickness of the layer may be up to 100 nm. Preferably however the thickness is less than 20 nm, even more preferably less than 5 nm.

The substrate is not limited to ITO-PET. Other materials may be used, for example but not limited to, ITO-PEN, transparent conductive oxide (TCO) coated film support materials, TCO coated glass.

The invention has been described in detail with reference to preferred embodiments thereof. It will be understood by those skilled in the art that variations and modifications can be effected within the scope of the invention.

1. A method of laying down one or more layers of material to reduce electrolytic reaction whilst allowing electron transfer between a conductive substrate and a light collecting charge separating layer, the layer being deposited between the conductive substrate and the light collecting charge separating layer and/or over the light collecting charge separating layer, the layer being deposited by simultaneously directing a series of gas flows along elongated channels such that the gas flows are substantially parallel to a surface of the substrate and substantially parallel to each other, whereby the gas flows are substantially prevented from flowing in the direction of the adjacent elongated channels, and wherein the series of gas flows comprises, in order, at least a first reactive gaseous material, inert purge gas, and a second reactive gaseous material, optionally repeated a plurality of times, wherein the first reactive gaseous material is capable of reacting with a substrate surface treated with the second reactive gaseous material.

2. A method as claimed in claim 1 wherein the light collecting charge separating layer is dye sensitised.

3. A method as claimed in claim 1 wherein the layer to reduce electrolytic reaction allowing electron transfer is a metal nitride or the compound formed from a metal and a group VI element.

4. A method as claimed in claim 3 wherein at least one layer to reduce electrolytic reaction allowing electron transfer is formed of titanium dioxide.

5. A method as claimed in claim 3 wherein at least one layer to reduce electrolytic reaction allowing electron transfer is formed of zinc oxide

6. A method as claimed in claim 1 wherein each of the layers to reduce electrolytic reaction allowing electron transfer has a thickness of less than 100 nm.

7. A method as claimed in claim 6 wherein each of the layers to reduce electrolytic reaction allowing electron transfer has a thickness of less than 20 nm.

8. A method as claimed in claim 7 wherein each of the layers to reduce electrolytic reaction allowing electron transfer has a thickness of less than 5 nm.

9. A method of fabricating a photovoltaic cell comprising a layer laid down as claimed in claim 1.

10. A photovoltaic cell comprising a layer fabricated by the method claimed in claim 1.
